(19) United States
(12) Patent Application Publication
(10) Pub. No.: US 2018/0073143 A1
(43) Pub. Date: Mar. 15, 2018

(54) PLASMA PROCESSING APPARATUS AND PLASMA PROCESSING METHOD

(71) Applicant: TOSHIBA MEMORY CORPORATION, Minato-ku (JP)

(72) Inventor: Hideaki MASUDA, Nagoya (JP)

(73) Assignee: TOSHIBA MEMORY CORPORATION, Minato-ku (JP)

(21) Appl. No.: 15/404,636

(22) Filed: Jan. 12, 2017

Related U.S. Application Data
(60) Provisional application No. 62/393,199, filed on Sep. 12, 2016.

(51) Int. Cl. C23C 16/50; C23C 16/52; C23C 16/455; C23C 16/24

(52) U.S. Cl. CPC C23C 16/50; C23C 16/24; C23C 16/455; C23C 16/52

(57) ABSTRACT

According to one embodiment, the distance measuring device measures a distance in the first direction between the first plate electrode and the second plate electrode at three or more locations. The correcting device causes a plurality of sections of at least one of the first plate electrode or the second plate electrode to be movable in the first direction. The plurality of sections are separated from each other in a planar direction. The controller drives the correcting device based on a measurement result of the distance measuring device and moves at least one section of the plurality of sections of the at least one of the first plate electrode or the second plate electrode in the first direction.

### CROSS-REFERENCE TO RELATED APPLICATION

This application is based upon and claims the benefit of priority from U.S. Provisional Patent Application 62/393,199, filed on Sep. 12, 2016; the entire contents of which are incorporated herein by reference.

### FIELD

Embodiments described herein relate generally to a plasma processing apparatus and a plasma processing method.

### BACKGROUND

In a plasma processing apparatus including parallel plate electrodes, the planar fluctuation of the distance between the plate electrodes may cause, for example, fluctuation of the planar distribution of the stress of a film formed on a wafer. The fluctuation of the planar distribution of the film stress may cause warp of the wafer.

### BRIEF DESCRIPTION OF THE DRAWINGS

FIGS. 1A and 1B are schematic views of a plasma processing apparatus of an embodiment;

FIGS. 2A and 2B are schematic views of a correcting device of the embodiment;

FIG. 3 is a control system diagram of the plasma processing apparatus of the embodiment;

FIG. 4 is a flowchart of a plasma processing method of the embodiment; and

FIG. 5 is a schematic cross-sectional view of a plasma processing object of the embodiment.

### DETAILED DESCRIPTION

According to one embodiment, a plasma processing apparatus includes a first plate electrode, a second plate electrode, a chamber, a distance measuring device, a correcting device, and a controller. The second plate electrode faces the first plate electrode and is separated from the first plate electrode in a first direction. The chamber houses the first plate electrode and the second plate electrode. The distance measuring device measures a distance in the first direction between the first plate electrode and the second plate electrode at three or more locations. The correcting device causes a plurality of sections of at least one of the first plate electrode or the second plate electrode to be movable in the first direction. The plurality of sections are separated from each other in a planar direction. The controller drives the correcting device based on a measurement result of the distance measuring device and moves at least one section of the plurality of sections of the at least one of the first plate electrode or the second plate electrode in the first direction.

Embodiments are described below with reference to the drawings. In the drawings, the same components are denoted by the same reference numerals and signs.

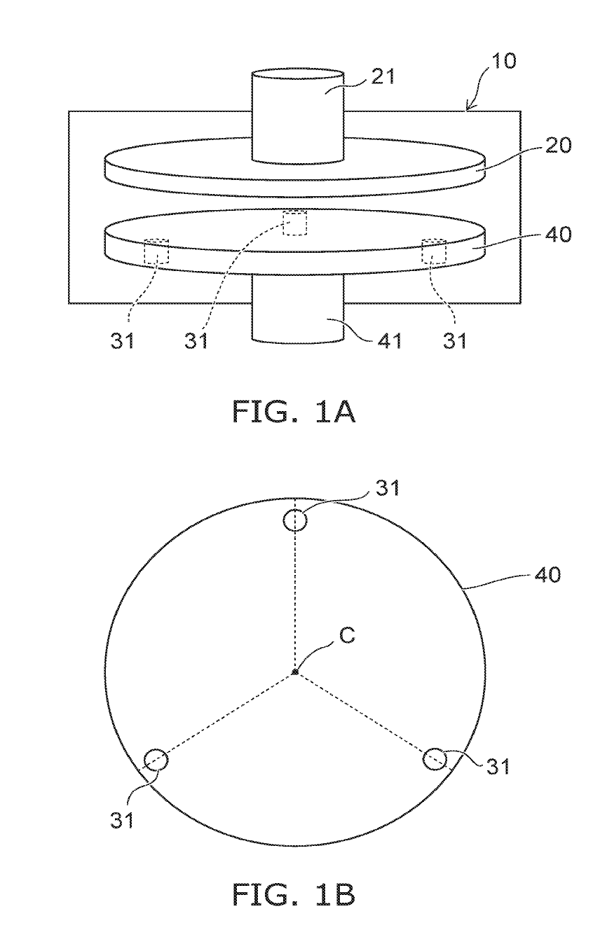

FIG. 1A is a schematic view of the plasma processing apparatus of the embodiment.

The plasma processing apparatus of the embodiment includes a chamber 10, and two plate electrodes (a first plate electrode 20 and a second plate electrode 40) housed inside the chamber 10.

The first plate electrode 20 and the second plate electrode 40 are separated from each other in a first direction inside the chamber 10 and face to each other. According to the embodiment, the first direction is, for example, the vertical direction. Or, the first plate electrode 20 and the second plate electrode 40 may be separated from each other and face to each other in the horizontal direction as the first direction.

The second plate electrode (the lower electrode) 40 is a heater pedestal having a built-in heater. For example, a wafer is supported on the second plate electrode 40 as an object of plasma processing.

The first plate electrode (the upper electrode) 20 is arranged above the second plate electrode 40. For example, the first plate electrode 20 functions also as a shower head introducing a gas into the chamber 10.

The interior of the chamber 10 is set to a prescribed reduced-pressure atmosphere by a not-illustrated exhaust system connected to the chamber 10. Then, in the state in which a gas is introduced to the chamber 10 through the first plate electrode (the shower head) 20, electrical power (e.g., high frequency power) is applied between the first plate electrode 20 and the second plate electrode 40; and plasma is generated between the first plate electrode 20 and the second plate electrode 40.

The plasma processing apparatus of the embodiment includes a distance measuring device that measures the distance in the first direction (the distance in the vertical direction) between the first plate electrode 20 and the second plate electrode 40 at three or more locations. The distance measuring device includes multiple distance measurers 31 arranged at the second plate electrode 40 inside the chamber 10.

FIG. 1B is a schematic plan view of the surface of the second plate electrode 40 facing the first plate electrode 20.

The surface of the second plate electrode 40 facing the first plate electrode 20 is substantially circular; and the surface of the first plate electrode 20 facing the second plate electrode 40 also is substantially circular.

According to the embodiment, for example, three distance measurers 31 are arranged to be separated from each other in the planar direction of the second plate electrode 40 at substantially uniform spacing (about 120° spacing). The distance measurers 31 face the first plate electrode 20 and measure the distance between the first plate electrode 20 and the second plate electrode 40 respectively at the locations where the distance measurers 31 are provided.

The distance measurers 31 are arranged on the outer perimeter side of the second plate electrode 40. The distance measurers 31 are positioned further on the outer perimeter side of a center C in the planar direction of the second plate electrode 40 on straight lines (illustrated by broken lines in FIG. 1B) passing through the center C and passing through the arrangement positions of the distance measurers 31.

The distance measurers 31 are, for example, electrostatic-capacitance type distance measurers; and the electrostatic capacitance between the first plate electrode 20 and the second plate electrode 40 is converted to the distance between the first plate electrode 20 and the second plate electrode 40 at the locations where the distance measurers 31 are arranged.

The distance measurers 31 may be arranged at the first plate electrode 20. Also, the distance measurers 31 may be, for example, distance measurers using laser light, etc.

The first plate electrode 20 and the second plate electrode 40 are held in a state of facing each other by holding members. Also, correcting devices described below are provided at the holding members.

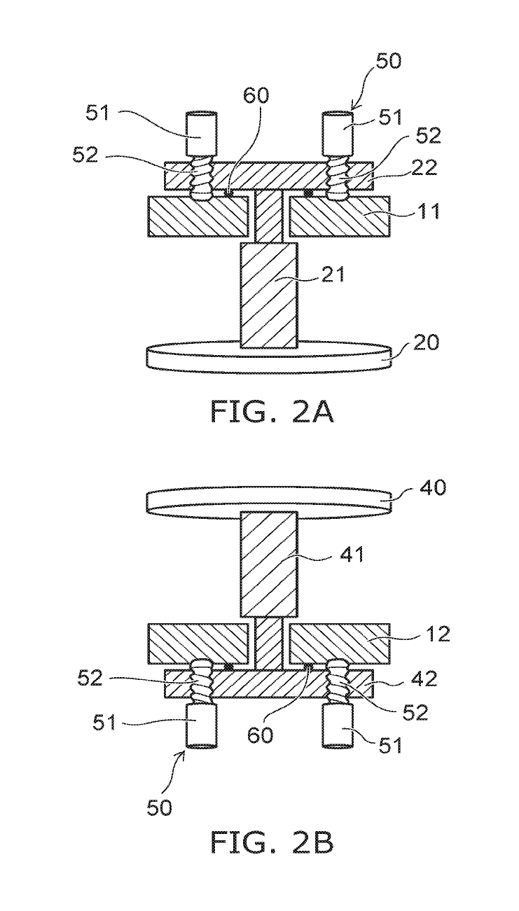

FIG. 2A is a schematic view of a holding member 22 and a correcting device 50 on the first plate electrode 20 side.

FIG. 2B is a schematic view of a holding member 42 and the correcting device 50 on the second plate electrode 40 side.

An axial unit 21 of the holding member 22 is provided at the central portion in the planar direction of the first plate electrode 20; and the axial unit 21 pierces a chamber lid 11 provided above the first plate electrode 20. The chamber lid 11 is included in the upper wall of the chamber 10 and is a stationary body.

The upper end of the axial unit 21 is coupled to the holding member 22. For example, the holding member 22 is formed in a disk configuration and faces the chamber lid 11 above the chamber lid 11.

The holding member 22 is mounted to the chamber lid 11 so that vertical movement (movement in the first direction) is possible. The correcting device 50 causes vertical movement of the holding member 22.

The correcting device 50 includes, for example, electric motors 51 as multiple drive devices. More specifically, the electric motors 51 are stepper motors.

The three electric motors 51 of the same number as the three distance measurers 31 are arranged to be separated at substantially uniform spacing (about 120° spacing) in the planar direction of the holding member 22 having the disk configuration.

When viewed from directly above the holding member 22 and the first plate electrode 20, the electric motors 51 are arranged respectively at substantially the same positions as the arrangement positions (overlapping positions) of the distance measurers 31. Or, the electric motors 51 are arranged respectively on the straight lines (the broken lines) passing through the center C in the planar direction of the second plate electrode 40 and passing through the arrangement positions of the distance measurers 31 shown in FIG. 1B. The center in the planar direction of the first plate electrode 20 matches the center C in the planar direction of the second plate electrode 40.

The correcting device 50 includes transmission members that convert the rotational motion of the electric motors 51 into linear motion in the vertical direction and transmit the linear motion to the holding member 22 and the first plate electrode 20. For example, the transmission member is a screw shaft 52 linked to the rotation shaft of the electric motor 51. The screw shaft 52 is coupled to a threaded hole formed in the holding member 22; and the tip (the lower end) of the screw shaft 52 is supported by the chamber lid 11.

When the screw shaft 52 rotates due to the driving of the electric motor 51, the joining portion of the holding member 22 with the screw shaft 52 moves vertically with respect to the chamber lid 11 which is a stationary body.

The electric motors 51, the screw shafts 52, and the holding member 22 are provided above the chamber lid 11, that is, outside the chamber 10.

An O-ring 60 is provided at the periphery of the axial unit 21 between the holding member 22 and the chamber lid 11. The O-ring 60 is closely adhered to the holding member 22 and the chamber lid 11. The space on the inner perimeter side of the O-ring 60 communicates with the space inside the chamber below the chamber lid 11. The O-ring 60 airtightly disconnects the space on the outer perimeter side of the O-ring 60 (ambient air) and the space on the inner perimeter side of the O-ring 60 (inside the chamber 10).

The holding member 42 and the correcting device 50 on the second plate electrode 40 side will now be described with reference to FIG. 2B.

The configuration of the correcting device 50 is the same for the first plate electrode 20 side and the second plate electrode 40 side. Also, it is sufficient for the correcting device 50 to be provided for at least one of the first plate electrode 20 side or the second plate electrode 40 side.

An axial unit 41 of the holding member 42 is provided at the central portion in the planar direction of the second plate electrode 40; and the axial unit 41 pierces a chamber body 12 provided below the second plate electrode 40. The chamber body 12 is included in the bottom wall of the chamber 10 and is a stationary body.

The lower end of the axial unit 41 is coupled to the holding member 42. For example, the holding member 42 is formed in a disk configuration and faces the chamber body 12 below the chamber body 12.

The holding member 42 is mounted to the chamber body 12 so that vertical movement (movement in the first direction) is possible. The correcting device 50 that includes the electric motors 51 and the screw shafts 52 causes vertical movement of the holding member 42.

The three electric motors 51 of the same number as the three distance measurers 31 are arranged to be separated at substantially uniform spacing (about 120° spacing) in the planar direction of the holding member 42 having the disk configuration.

When viewed from directly above the second plate electrode 40 and the holding member 42, the electric motors 51 are arranged respectively at substantially the same positions as the arrangement positions (overlapping positions) of the distance measurers 31. Or, the electric motors 51 are arranged respectively on the straight lines (the broken lines) passing through the center C in the planar direction of the second plate electrode 40 and passing through the arrangement positions of the distance measurers 31 shown in FIG. 1B.

The screw shaft 52 that is linked to the rotation shaft of the electric motor 51 is coupled to a threaded hole formed in the holding member 42; and the tip (the upper end) of the screw shaft 52 is supported by the chamber body 12.

When rotating the screw shaft 52 by the driving of the electric motor 51, the joining portion of the holding member 42 with the screw shaft 52 moves vertically with respect to the chamber body 12 which is a stationary body.

The electric motors 51, the screw shafts 52, and the holding member 42 are provided below the chamber body 12, that is, outside the chamber 10.

The O-ring 60 is provided at the periphery of the axial unit 41 between the holding member 42 and the chamber body 12. The O-ring 60 is closely adhered to the holding member 42 and the chamber body 12. The space on the inner perimeter side of the O-ring 60 communicates with the space inside the chamber 10 above the chamber body 12. The O-ring 60 airtightly disconnects the space on the outer perimeter side of the O-ring 60 (ambient air) and the space on the inner perimeter side of the O-ring 60 (inside the chamber 10).

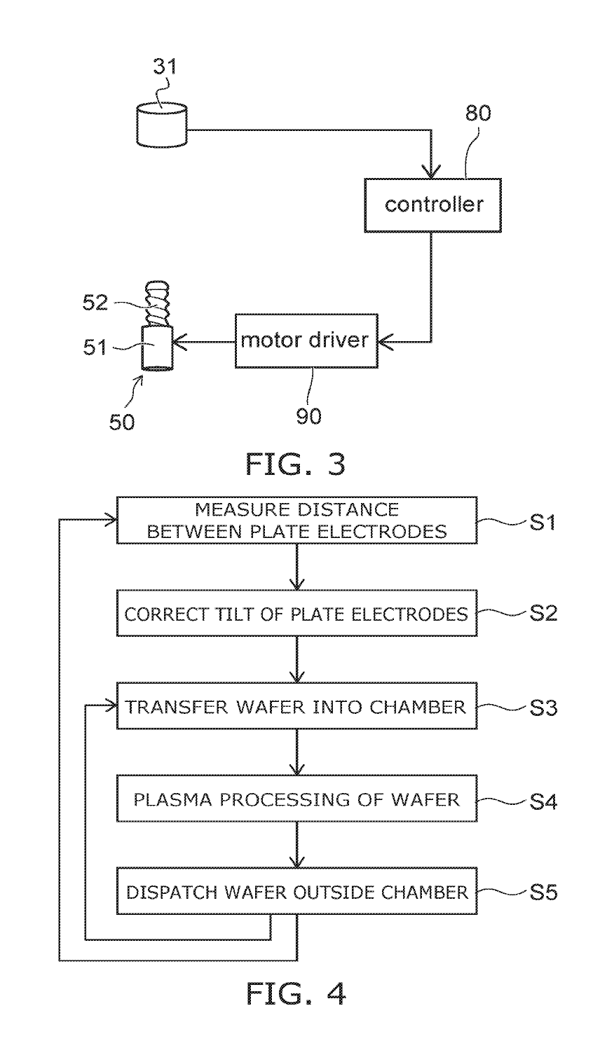

FIG. 3 is a control system diagram of the plasma processing apparatus of the embodiment.

The plasma processing apparatus of the embodiment further includes a controller 80 and a motor driver 90.

The controller 80 receives the measurement result (the measurement signals) of the distance measurers 31 and controls the motor driver 90 based on the measurement result. Then, the rotation speed or the rotation angle of the electric motor 51 which is a stepper motor is controlled by, for example, a pulse control from the motor driver 90; and the movement amount in the vertical direction of the holding members 22 and 42 coupled to the screw shaft 52 is controlled.

The controller 80 controls the movement amount in the vertical direction of the section of the first plate electrode 20 held by the holding member 22 or the second plate electrode 40 held by the holding member 42 where the correcting device 50 is arranged based on the measurement result of the distance measurers 31.

The multiple electric motors 51 each are controlled independently. Accordingly, the amounts moving in the vertical direction of the multiple sections (e.g., three sections) of the first plate electrode 20 corresponding to the arrangement position of the correcting device 50 each are controlled independently. Similarly, the amounts moving in the vertical direction of the multiple sections (e.g., the three sections) of the second plate electrode 40 corresponding to the arrangement position of the correcting device 50 each are controlled independently.

Four or more distance measurers 31 may be arranged at the first plate electrode 20 or the second plate electrode 40; and the distance between the first plate electrode 20 and the second plate electrode 40 may be measured at four or more locations. Also, sections of the first plate electrode 20 at four or more locations may be configured to be vertically moveable. Similarly, sections of the second plate electrode 40 at four or more locations may be configured to be vertically moveable.

FIG. 4 is a flowchart of a plasma processing method using the plasma processing apparatus of the embodiment.

In step S1, the distance between the first plate electrode 20 and the second plate electrode 40 is measured. The distance in the first direction (the vertical direction) between the first plate electrode 20 and the second plate electrode 40 is measured at three locations using the three distance measurers 31 described above.

When measuring the distance, the wafer which is the processing object is not housed inside the chamber 10. For example, the distance measurement is performed at a timing after the wafer for which the processing has ended is dispatched outside the chamber 10 and before the wafer to be processed next is transferred into the chamber 10.

Also, the distance measurement is performed in the state in which the interior of the chamber 10 is not opened to ambient air and further in the state in which the heater built into the second plate electrode 40 is operated. The wafer processing after the distance measurement can be started rapidly by maintaining the conditions in the distance measurement to be nearly those of the wafer processing as well. Also, distance measurement that reflects the distance between the first plate electrode 20 and the second plate electrode 40 in the actual wafer processing is possible.

According to the embodiment, for example, because the electrostatic-capacitance type distance measurers 31 are used, the measurement of the distance is performed without generating the plasma that may affect the distance measurement.

Because the distance measurers 31 are arranged further on the outer perimeter side of the second plate electrode 40 than the wafer-holding surface, the distance measurement is possible even in the state in which the wafer is held by the second plate electrode 40.

After measuring the distance between the first plate electrode 20 and the second plate electrode 40, in step S2, the first plate electrode 20 or the second plate electrode 40 or both the first plate electrode 20 and the second plate electrode 40 are moved in the first direction (the vertical direction) by driving the correcting device 50 by the control of the controller 80 based on the measurement result.

The first plate electrode 20 is moved in the vertical direction together with the holding member 22 by the driving of the correcting device 50. At least one of the three electric motors 51 is driven; and at least one section of the three sections of the first plate electrode 20 separated from each other in the planar direction corresponding to the arrangement position of the driven electric motor 51 is moved in the vertical direction. The amount that the one section is moved in the vertical direction by one correction is, for example, about ( 1/1000) inch.

For example, among the measurement locations of the distances at the three locations by the distance measurers 31 (the arrangement positions of the distance measurers 31), in the case where the distance at a first location and the distance at a second location are substantially the same but the distance at a third location is different from the distance at the first location and the distance at the second location, the distance at the third location can be caused to match the distance at the first location and the distance at the second location by driving the electric motor 51 arranged at the third location or arranged on the line (the broken line of FIG. 1B) passing through the third location and the center C of the plate electrodes 20 and 40.

The distance to the second plate electrode 40 is corrected for at least one section of the multiple sections of the first plate electrode 20. Thereby, the tilt of the first plate electrode 20 with respect to the second plate electrode 40 is corrected; for example, the first plate electrode 20 is corrected to face the second plate electrode 40 parallel to the second plate electrode 40.

As necessary, the correcting device 50 on the second plate electrode 40 side also is driven; and the second plate electrode 40 is moved in the vertical direction together with the holding member 42. At least one of the three electric motors 51 on the second plate electrode 40 side is driven; and at least one section of the three sections of the second plate electrode separated from each other in the planar direction corresponding to the arrangement position of the driven electric motor 51 is moved in the vertical direction. The distance to the first plate electrode 20 is corrected at the at least one section of the multiple sections of the second plate electrode 40.

The tilt in at least two directions of the surface, i.e., the tilt of the surface, of the first plate electrode 20 or the second plate electrode 40 can be corrected by using a configuration in which it is possible to measure the distance between the first plate electrode 20 and the second plate electrode 40 at three or more locations and move the sections of the first plate electrode 20 or the second plate electrode 40 at three or more locations in the first direction (the vertical direction).

Causing the first plate electrode 20 and the second plate electrode 40 to face and be parallel to each other means the decrease of the planar fluctuation of the distance between the first plate electrode 20 and the second plate electrode 40. This reduces the planar fluctuation of the electro-discharge power (the high frequency power) between the first plate electrode 20 and the second plate electrode 40 and reduces the planar fluctuation of the plasma processing of the wafer.

The correction of the distance of the first plate electrode 20 and the second plate electrode 40 is not limited to causing the first plate electrode 20 and the second plate electrode 40 to face and be parallel to each other. Also, there may be a correction to cause the distance between the first plate electrode 20 and the second plate electrode 40 at any section to be different from the distance at another section based on a processing result or processing requirements of the wafer.

After correcting the distance recited above, the wafer is transferred into the chamber 10 in step S3. Then, plasma processing of the wafer is performed in step S4. For example, the plasma Chemical Vapor Deposition (CVD), plasma etching, plasma doping, or the like is performed as the plasma processing.

Here, film formation by plasma CVD is described. A source gas is introduced to the chamber 10; for example, high frequency power is applied between the first plate electrode 20 and the second plate electrode 40; and plasma is generated between the first plate electrode 20 and the second plate electrode 40. Then, a film that includes an element included in the source gas is formed on the wafer held on the second plate electrode 40.

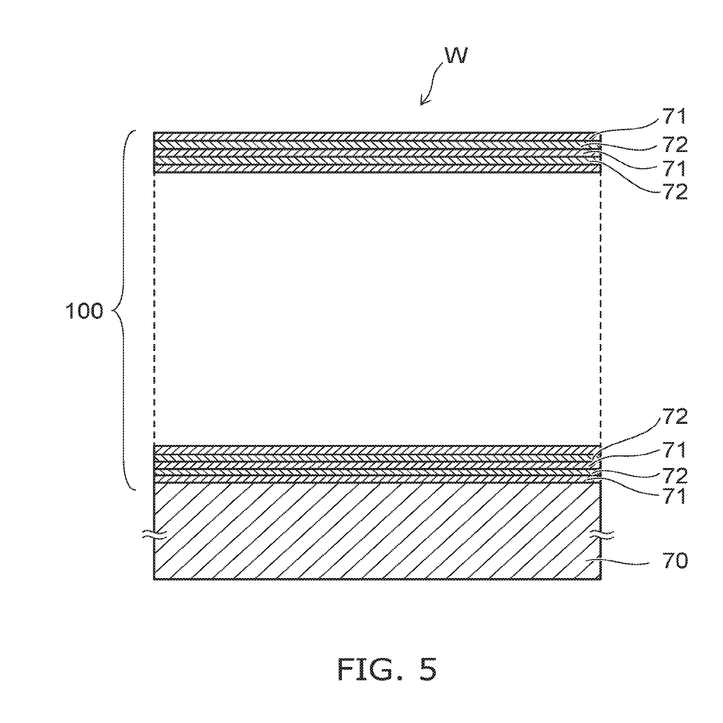

FIG. 5 is a schematic cross-sectional view of a wafer W used as the plasma CVD object of the embodiment.

The wafer W has a structure in which a stacked film 100 is formed on a substrate 70. The substrate 70 is a semiconductor substrate, e.g., a silicon substrate.

The stacked film 100 includes multiple first films 71 and multiple second films 72. A process of alternately forming the first films 71 and the second films 72 on the substrate 70 by plasma CVD is multiply repeated.

The second films 72 are, for example, silicon oxide films. The first films 71 are films of a material different from the second films 72 and are, for example, silicon nitride films or metal films.

In particular, the silicon nitride films that are formed by plasma CVD may have a large stress. In the plasma CVD, the planar fluctuation of the distance between the first plate electrode 20 and the second plate electrode 40 may be caused by the planar fluctuation of the high frequency power between the first plate electrode 20 and the second plate electrode 40. Then, the planar fluctuation of the high frequency power affects the planar distribution of the stress of the films (particularly, the silicon nitride films). The planar distribution of the film stress affects the warp of the wafer W. The warp of the wafer may cause shifting of the alignment of the lithography of subsequent processes.

According to the embodiment as described above, the warp of the wafer W can be suppressed by reducing the planar fluctuation of the distance between the first plate electrode 20 and the second plate electrode 40 or by controlling the planar distribution of the film stress by appropriately correcting the planar distribution. Accordingly, the lithography of the subsequent processes is performed appropriately.

After the plasma processing of the wafer has ended, the wafer is dispatched outside the chamber 10 in step S5.

Then, returning to step S3, the next wafer is transferred into the chamber 10; and plasma processing of the wafer is performed.

Or, after the processing of the wafer has ended, returning to step S1 as necessary, the distance measurement between the first plate electrode 20 and the second plate electrode 40 described above and the correction of the distance between the first plate electrode 20 and the second plate electrode 40 based on the measurement result are performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A plasma processing apparatus, comprising:
a first plate electrode;
a second plate electrode facing the first plate electrode and being separated from the first plate electrode in a first direction;
a chamber housing the first plate electrode and the second plate electrode;
a distance measuring device measuring a distance in the first direction between the first plate electrode and the second plate electrode at three or more locations;
a correcting device causing a plurality of sections of at least one of the first plate electrode or the second plate electrode to be movable in the first direction, the plurality of sections being separated from each other in a planar direction; and
a controller driving the correcting device based on a measurement result of the distance measuring device and moving at least one section of the plurality of sections of the at least one of the first plate electrode or the second plate electrode in the first direction.

2. The plasma processing apparatus according to claim 1, wherein amounts of the sections moving in the first direction are controlled independently.

3. The plasma processing apparatus according to claim 1, wherein the distance measuring device includes three or more distance measurers arranged at substantially uniform spacing on an outer perimeter side of the first plate electrode or the second plate electrode.

4. The plasma processing apparatus according to claim 3, wherein the distance measurers are provided at one of the first plate electrode or the second plate electrode inside the chamber and face the other of the first plate electrode or the second plate electrode.

5. The plasma processing apparatus according to claim 3, wherein the distance measurers are electrostatic-capacitance type distance measurers.

6. The plasma processing apparatus according to claim 3, wherein
the correcting device includes three or more drive devices of the same number as the three or more distance measurers, and
the three or more drive devices each are driven and controlled independently.

7. The plasma processing apparatus according to claim 6, wherein the drive devices each are arranged respectively on straight lines passing through a center in a planar direction of at least one of the first plate electrode or the second plate electrode and passing through arrangement positions of the distance measurers.

8. The plasma processing apparatus according to claim 6, wherein
the drive device is an electric motor,
the controller controls the electric motor based on the measurement result, and
the correcting device includes a transmission member converting a rotational motion of the electric motor into a linear motion in the first direction and transmitting the linear motion to the first plate electrode or the second plate electrode.

9. The plasma processing apparatus according to claim 8, wherein
the transmission member is a screw shaft linked to a rotation shaft of the electric motor, and
the screw shaft is coupled to a holding member of at least one of the first plate electrode or the second plate electrode.

10. The plasma processing apparatus according to claim 9, wherein the electric motor, the screw shaft, and the holding member are provided outside the chamber.

11. A plasma processing method generating plasma between a first plate electrode and a second plate electrode inside a chamber, the first plate electrode and the second plate electrode facing each other and being separated from each other in a first direction, the plasma processing method comprising:
moving in the first direction at least one section of a plurality of sections of at least one of the first plate electrode or the second plate electrode by a control of a controller based on a measurement result of a distance in the first direction between the first plate electrode and the second plate electrode at three or more locations, the plurality of sections being separated from each other in a planar direction.

12. The plasma processing method according to claim 11, wherein amounts of the sections moving in the first direction are controlled independently.

13. The plasma processing method according to claim 11, wherein the distance is measured in a state in which the plasma is not generated inside the chamber.

14. The plasma processing method according to claim 11, wherein the distance is measured in a state in which an interior of the chamber is not opened to ambient air, and subsequently at least the one section of the at least one of the first plate electrode or the second plate electrode is moved in the first direction without opening the interior of the chamber to ambient air.

15. The plasma processing method according to claim 11, wherein a source gas is introduced to the chamber, and a film including an element included in the source gas is formed on a wafer held by the first plate electrode or the second plate electrode.

16. The plasma processing method according to claim 15, wherein
the film is a stacked film of a first film and a second film, the second film being of a material different from the first film, and
a process of alternately stacking the first film and the second film is multiply repeated.

17. The plasma processing method according to claim 16, wherein the first film is a silicon nitride film, and the second film is a silicon oxide film.

18. The plasma processing method according to claim 16, wherein the first film is a metal film, and the second film is a silicon oxide film.
